(19) United States
(12) Patent Application Publication
(10) Pub. No.: US 2024/0429116 A1
(43) Pub. Date: Dec. 26, 2024

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Seoung Joon HONG, Incheon (KR); Se Il JUNG, Incheon (KR); Dong Hee KANG, Gyeonggi-do (KR)

(73) Assignee: Amkor Technology Singapore Holding Pte. Ltd., Valley Point #12-03 (SG)

(21) Appl. No.: 18/213,862

(22) Filed: Jun. 25, 2023

(51) Int. Cl. H01L 23/31; H01L 23/00; H01L 23/29; H01L 23/367; H01L 23/552; H01L 25/065; H01L 25/16

(52) U.S. Cl. CPC H01L 23/3128; H01L 23/29; H01L 23/3107; H01L 23/3675; H01L 23/552; H01L 24/05; H01L 24/13; H01L 24/16; H01L 24/29; H01L 24/30; H01L 24/33; H01L 24/73; H01L 24/81; H01L 24/83; H01L 24/92; H01L 25/0655; H01L 25/165; H01L 2224/05573; H01L 2224/05611; H01L 2224/05616; H01L 2224/05624; H01L 2224/05639; H01L 2224/05644; H01L 2224/05647; H01L 2224/05655; H01L 2224/05664; H01L 2224/05666; H01L 2224/05684; H01L 2224/13111; H01L 2224/13116; H01L 2224/13124; H01L 2224/13139; H01L 2224/13144; H01L 2224/13147; H01L 2224/13155; H01L 2224/13164; H01L 2224/13166; H01L 2224/13184; H01L 2224/16227; H01L 2224/26175; H01L 2224/29105; H01L 2224/29109; H01L 2224/29111; H01L 2224/29118; H01L 2224/29139; H01L 2224/2919; H01L 2224/30505; H01L 2224/32013; H01L 2224/32225; H01L 2224/32245; H01L 2224/33181; H01L 2224/33183; H01L 2224/73204; H01L 2224/73253; H01L 2224/81203; H01L 2224/81224; H01L 2224/81815; H01L 2224/83007; H01L 2224/831; H01L 2224/83192; H01L 2224/83815; H01L 2224/92125; H01L 2224/922; H01L 2924/0132; H01L 2924/0665; H01L 2924/069; H01L 2924/07025

(57) ABSTRACT

In one example, an electronic device includes a substrate including a substrate outer side, a substrate inner side, a dielectric structure, and a conductive structure. An electronic component includes an upper side, a lower side opposite to the upper side and coupled to the substrate inner side; a lateral side connecting the upper side to the lower side; and a conductor on the upper side. A cover structure includes sidewalls coupled to the substrate inner side and an upper wall coupled to the sidewalls and comprising an inner side spaced apart from the conductor. A thermal interface material (TIM) contacts and is interposed between the conductor and the inner side of the upper wall. The TIM covers the conductor and the lateral side of the electronic component. Other examples and related methods are also disclosed herein.

### CROSS-REFERENCE TO RELATED APPLICATIONS

Not Applicable.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, and 2G show cross-sectional views of an example method for manufacturing an example electronic device.

FIG. 3 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements.

### DESCRIPTION

In an example, an electronic device includes a substrate including a substrate outer side, a substrate inner side, a dielectric structure, and a conductive structure. An electronic component includes an upper side, a lower side opposite to the upper side and coupled to the substrate inner side; a lateral side connecting the upper side to the lower side; and a conductor on the upper side. A cover structure includes sidewalls coupled to the substrate inner side and an upper wall coupled to the sidewalls and comprising an inner side spaced apart from the conductor. A thermal interface material (TIM) contacts and is interposed between the conductor and the inner side of the upper wall. The TIM covers the conductor and the lateral side of the electronic component.

In an example, an electronic device includes a substrate including a substrate outer side, a substrate inner side, a dielectric structure, and a conductive structure. A first electronic component includes a lower side coupled to the substrate inner side, an upper side opposite to the lower side and distal to the substrate inner side, and lateral sides connecting the upper side to the lower side. A cover structure includes sidewalls coupled to the substrate inner side and an upper wall coupled to the sidewalls and comprising an inner side spaced apart from and overlying the upper side of the first electronic component. A thermal interface material (TIM) is interposed between the upper side of the first electronic component and the inner side of the upper wall. The TIM covers the upper side and the lateral sides of the first electronic component and the TIM is coupled to the conductive structure.

In an example, A method of manufacturing an electronic device includes providing a substrate including a substrate outer side, a substrate inner side, a dielectric structure, and a conductive structure. The method includes providing an electronic component including an upper side, a lower side opposite to the upper side and coupled to the substrate inner side, lateral side connecting the upper side to the lower side, and a conductor on the upper side. The method includes coupling the lower side of the electronic component to the substrate inner side. The method includes providing a cover structure comprising sidewalls and an upper wall coupled to the sidewalls and comprising an inner side spaced apart from the conductor. The method includes coupling the sidewalls to the substrate inner side. The method includes providing a thermal interface material (TIM) on the conductor and interposed between the conductor and the inner side of the upper wall and covering the conductor and the lateral side of the electronic component.

Other examples are included in the present disclosure. Such examples may be found in the figures, in the claims, or in the description of the present disclosure.

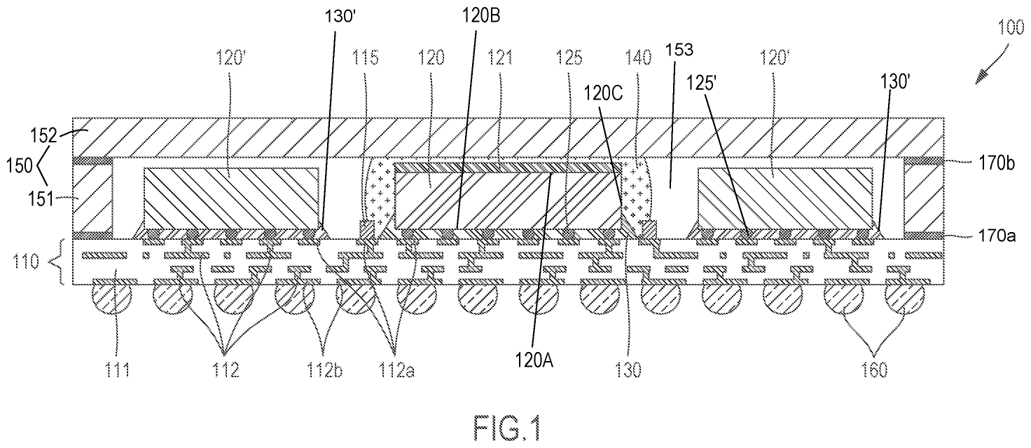

FIG. 1 shows a cross-sectional view of an example electronic device 100. In the example shown in FIG. 1, electronic device 100 can comprise substrate 110, electronic component 120, underfill 130, thermal interface material (TIM) 140, cover structure 150, external interconnects 160, and bonding material 170a and 170b. In some examples, electronic device 100 can comprise one or more electronic components 120′.

Substrate 110 can comprise dielectric structure 111 and conductive structure 112. Conductive structure 112 can comprise substrate inward terminals 112a and substrate outward terminals 112b. Substrate 110 can comprise dam 115 laterally spaced apart from electronic component 120. In some examples, dam 115 can surround one or more sides of electronic component 120. Electronic component 120 can comprise conductor 121 at an upper side 120a distal to substrate 110 and component interconnects 125 at a lower side 120b proximate to substrate 110. Electronic component 120 can comprise a lateral side 120c connecting upper side 120a to lower side 120b. In some examples, underfill 130 can be interposed between lower side 120b and substrate 110 and can surround component interconnects 125. Cover structure 150 can comprise an upper wall 152 and sidewalls 151. In some examples, upper wall 152 and sidewalls 151 can be separate components. In some examples, upper wall 152 and sidewalls 151 can be a single-piece or an integrated structure. In some examples, sidewalls 151 are coupled to substrate 110 with bonding material 170a and upper wall 152 is coupled to sidewalls 151 with bonding material 170b. TIM 140 can cover or encapsulate electronic component 120 and affix cover structure 150 to conductor 121 of electronic device 120.

Substrate 110, cover structure 150, bonding materials 170a and 170b, TIM 140, and external interconnects 160 can comprise or be referred to as an electronic package or a package. The electronic package can protect electronic components 120 and 120′ from exposure to external elements and/or environments. The electronic package can also provide electrical coupling between electronic component 120 and electronic components 120′ and between electronic components 120 and 120′ and an external component or other electronic packages.

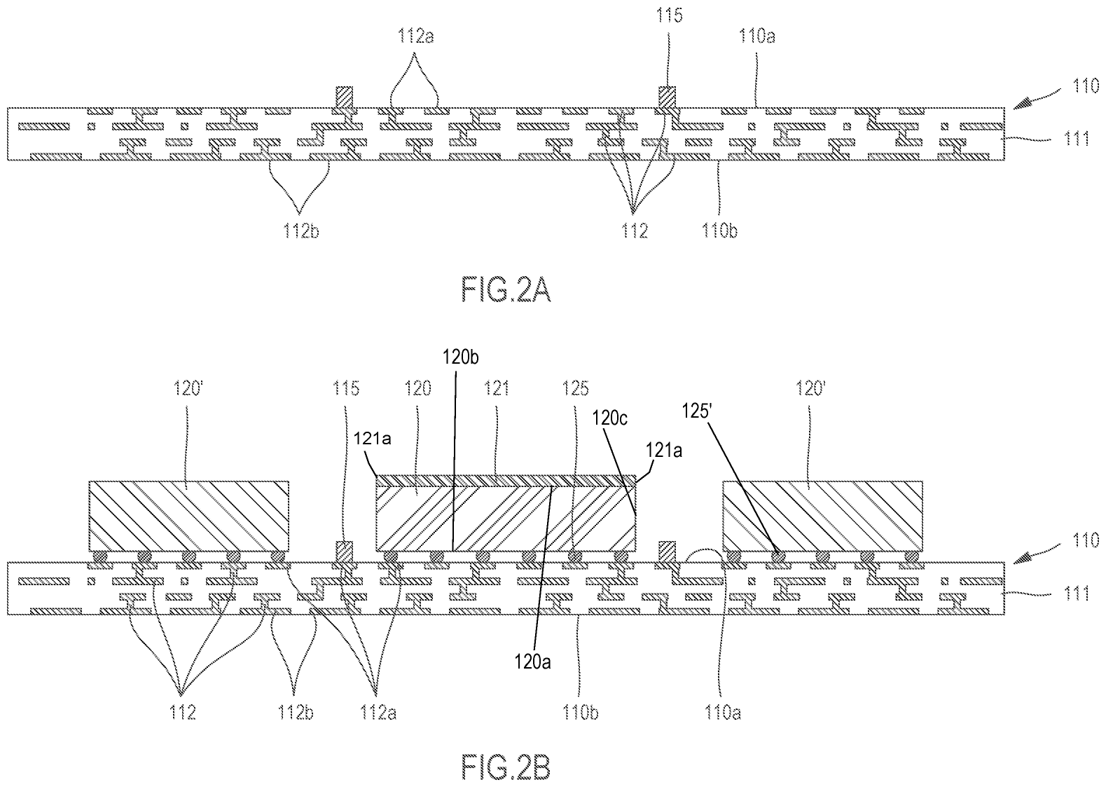

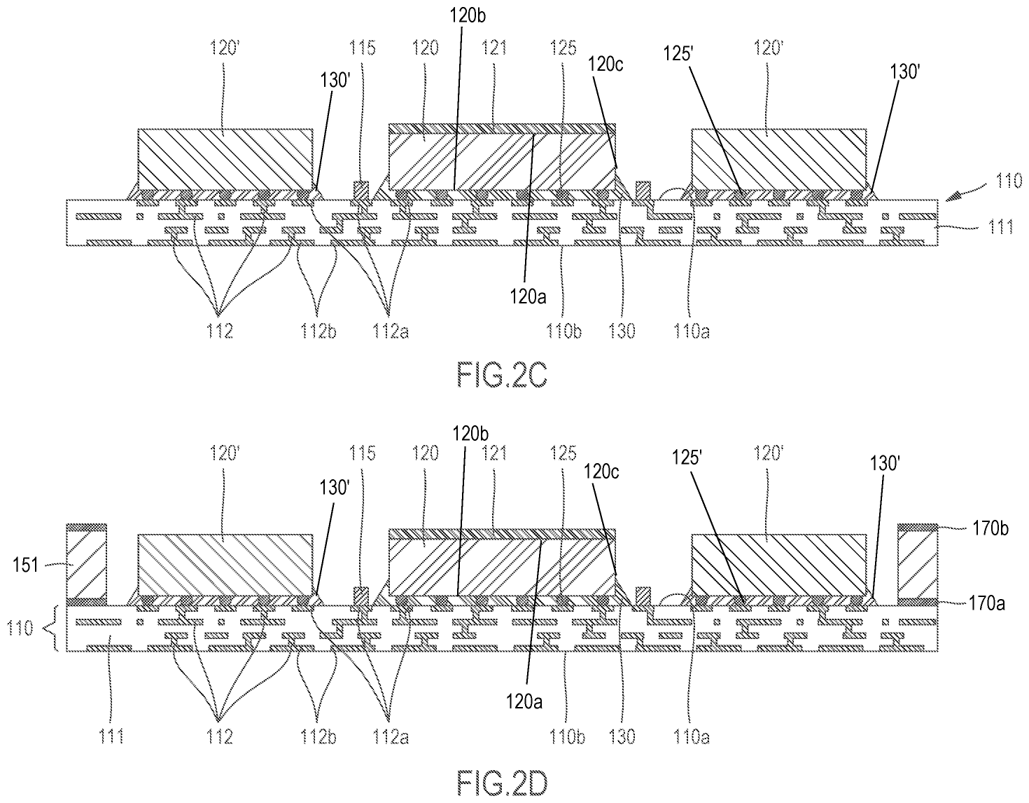

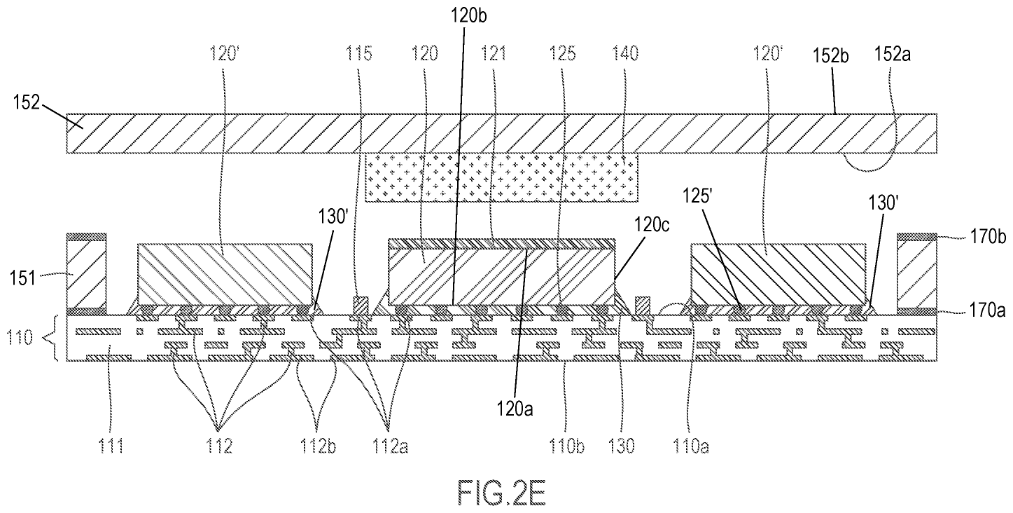

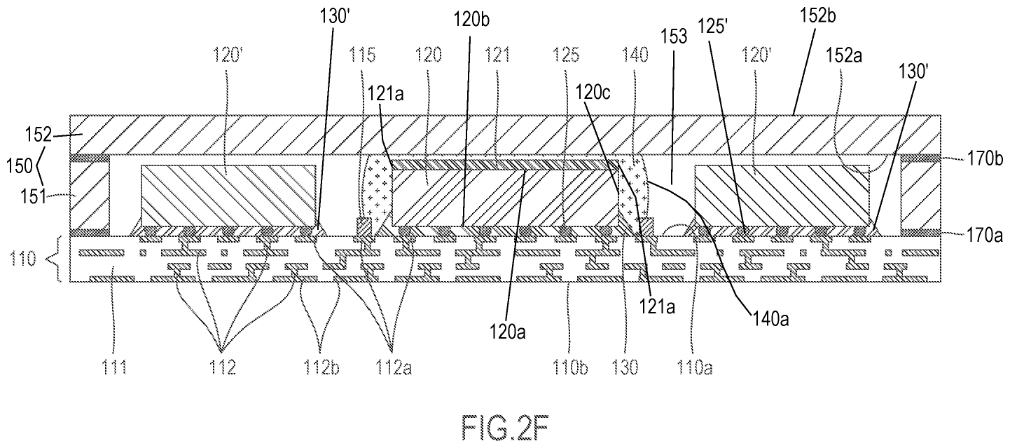

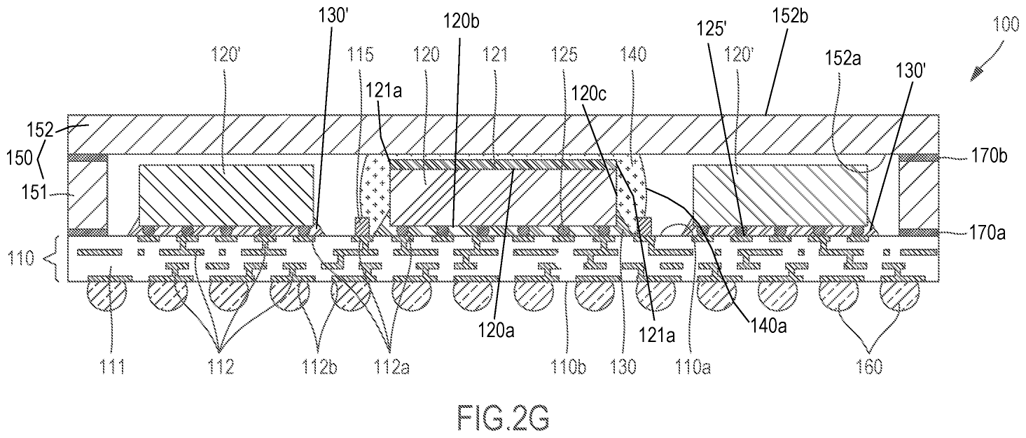

FIGS. 2A to 2G show cross-sectional views of an example method for manufacturing an example electronic device, such as electronic device 100 illustrated in FIG. 1.

FIG. 2A is a cross-sectional view of electronic device 100 at an early stage of manufacture. In the example shown in FIG. 2A, substrate 110 can be provided. In some examples, substrate 110 can comprise or be referred to as a laminate substrate, a redistribution layer (RDL) substrate, a rigid substrate, a glass substrate, a semiconductor substrate, a printed circuit board, a multi-layer substrate, a molded lead frame, or a ceramic substrate. Substrate 110 can comprise dielectric structure 111 and conductive structure 112.

In some examples, conductive structure 112 can comprise or be referred to as one or more conductors, conductive materials, conductive paths, conductive layers, RDLs, wiring layers, traces, vias, pads, or under bump metallization (UBM). In some examples, one or more of the conductive layers can be interleaved with dielectric layers of dielectric structure 111. In some examples, conductive structure 112 can comprise copper, aluminum, palladium, titanium, tungsten, titanium/tungsten, nickel, gold, or silver. In some examples, conductive structure 112 can be provided by sputtering, electroless plating, electrolytic plating, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or other processes as known to one of ordinary skill in the art. In some examples, a portion of conductive structure 112 can be exposed from a substrate inner side 110a and from a substrate outer side 110b of substrate 110. Substrate inner side 110a also can be referred to as substrate top side 110a, and substrate outer side 110b also can be referred to as substrate bottom side 110b.

Conductive structure 112 can include substrate inward terminals, inner contact pads, traces, or lands 112a and substrate outward terminals, outer contact pads, traces, or lands 112b. Inner contact pads 112a can be exposed from substrate inner side 110a of substrate 110 and outer contact pads 112b can be exposed from substrate outer side 110b of substrate 110. In some examples, inner contact pads 112a or outer contact pads 112b can be provided in a matrix form having rows or columns, respectively. Conductive structure 112 can be coupled to electronic components 120 and 120′ (FIG. 1) and external interconnects 160 (FIG. 1). For example, electronic components 120 and 120′ can be coupled to inner contact pads 112a and external interconnects 160 can be coupled to outer contact pads 112b. Conductive structure 112 can transmit signals, currents, or voltages within substrate 110. In some examples, the thickness of conductive structure 112 can range from about 3 μm to about 50 μm. The thickness of conductive structure 112 can refer to individual layers of conductive structure 112.

In some examples, dielectric structure 111 can comprise or be referred to as one or more dielectrics, dielectric materials, dielectric layers, passivation layers, insulating layers, or protective layers. In some examples, dielectric structure 111 can have a structure where one or more dielectric layers are stacked. In some examples, dielectric structure 111 can comprise a polymer, polyimide (PI), benzocyclobutene (BCB), polybenzoxazole (PBO), bismaleimide triazine (BT), a molding material, phenolic resin, epoxy, silicone, or acrylate polymer. Dielectric structure 111 can be in contact with conductive structure 112. Dielectric structure 111 can expose portions of conductive structure 112. In some examples, dielectric structure 111 can maintain the external shape of substrate 110 and can structurally support conductive structure 112 and electronic components 120 and 120′. In some examples, dielectric structure 111 can be provided by spin coating, spray coating, printing, oxidation, PVD, CVD, MOCVD, ALD, LPCVD, PECVD, or other processes as known to one of ordinary skill in the art. The upper and lower sides of dielectric structure 111 can be part of substrate inner side 110a and substrate outer side 1100 of substrate 110, respectively. Substrate outer side 110b can be opposite to the substrate inner side 110a. In some examples, the thicknesses of individual layers of dielectric structure 111 can range from about 3 μm to about 50 μm. The combined thickness of all layers of dielectric structure 111 can define the thickness of substrate 110. In some examples, the total thickness of dielectric structure 111 can range from about 10 μm (micrometers) to 500 μm.

In some examples, substrate 110 can comprise dam 115 coupled to substrate inner side 110a. In some examples, dam 115 can comprise a conductive material. For example, dam 115 can comprise a metal and can be coupled to inner contact pads 112a. In some examples, dam 115 can be coupled to ground through inner contact pads 112a and conductive structure 112. In some examples, dam 115 can be provided by deposition, evaporation, printing, plating, or sputtering. In some examples, dam 115 can comprise a ring shape, such as a flat rectangular ring, and can have a cavity therein. In some examples, the thickness of dam 115 can range from about 50 μm to about 200 μm. In some examples, the width (thickness in plane) of dam 115 can range from about 50 μm to about 500 μm.

In some examples, dam 115 can comprise a non-conductive material. For example, dam 115 can comprise a dielectric, such as an insulative polymer. In some examples and in addition to the methods described above, dam 115 can be applied through dispensing or printing, or can be attached in the form of a film or other pre-form structures. In other examples, dam 115 can be coupled to dielectric structure 111 at substrate inner side 110a.

In some examples, substrate 110 can have an area varying according to the area or number of electronic components 120 and 120′. In some examples, substrate 110 can have an area of about 8 mm (millimeter)×8 mm to about 150 mm×150 mm. In some examples, substrate 110 can have a thickness of about 0.2 mm to about 4 mm. In some examples, substrate 110 can be an RDL substrate. RDL substrates can comprise one or more conductive redistribution layers and one or more dielectric layers that (a) can be formed layer by layer over an electronic device to which the RDL substrate is to be electrically coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Substrates, as disclosed herein, can comprise RDL substrates.

In some examples, substrate 110 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate which omits the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Substrates, as disclosed herein, can comprise pre-formed substrates.

FIG. 2B shows a cross-sectional view of electronic device 100 at a later stage of manufacture. In the example shown in FIG. 2B, electronic component 120 can be provided on substrate inner side 110a of substrate 110. In some examples, electronic component 120 can be coupled to conductive structure 112 of substrate 110. For example, electronic component 120 can be coupled to inner contact pads 112a.

In some examples, electronic component 120 can comprise or be referred to as one or more dies, chips, or packages. In some examples, electronic component 120 can comprise a memory, a digital signal processor (DSP), a microprocessor, a network processor, a power management processor, an audio processor, an RF circuit, a wireless baseband system-on-chip (SoC) processor, a sensor, or an application specific integrated circuit (ASIC).

Electronic component 120 can be provided within the cavity of dam 115 on substrate inner side 110a. In some examples, dam 115 is laterally surrounds electronic component 120. In some examples, electronic component 120 can be located at the center of substrate inner side 110a of substrate 110. In some examples, in electronic component 120, lower side 120b can comprise or be referred to an active side, and upper side 120a can comprise or be referred to an inactive side. In some examples, upper side 120a is distal to substrate inner side 110a and lower side 120b is proximate to substrate inner side 110a. Electronic component 120 can comprise one or more lateral sides 120c connected to upper side 120a and lower side 120b. Dam 115 is laterally spaced apart from lateral sides 120c of electronic component 120 so that a portion of substrate inner side 110a is between dam 115 and electronic component 120. In some examples, the distance between lateral sides 120c of electronic component 120 and dam 115 can range from about 100 μm to about 2000 μm. In some examples, dam 115 continuously surrounds electronic device 120 without breaks or discontinuities.

Electronic component 120 can comprise conductor 121 over upper side 120a. In some examples, conductor 121 can comprise or be referred to as back side metallization (BSM) plating layer, a conductive film, or a conductive layer. For example, conductor 121 can be provided onto upper side 120a of electronic component by electroplating, electroless plating, evaporation, sputtering, or PVD. In some examples, conductor 121 comprises a deposited conductor or a plated conductor structure. In some examples, conductor 121 can comprise one or more of copper (Cu), lead (Pb), tin (Sn), aluminum (Al), palladium (Pd), titanium (Ti), tungsten (W), titanium/tungsten (Ti/W), nickel (Ni), gold (Au), or silver (Ag) In some examples, the thickness of conductor 121 can range from about 0.3 μm to about 3 μm. In present example, conductor 121 is provided as part of or a structural element of electronic component 120. In some examples, conductor 121 laterally extends to lateral sides 120c of electronic component 120. In some examples, lateral edges 121a of conductor 121 are substantially co-planar with lateral sides 120c of electronic component 120. In some examples, conductor 121 is other than or is not a structure formed onto TIM 140 and then placed onto upper side 120a electronic component as part of cover structure 150.

Electronic component 120 can comprise component interconnects 125 over lower side 120b. Component interconnects 125 can be provided adjacent to lower side 120b of electronic component 120 and spaced apart from each other in a row or column direction. Component interconnects 125 can comprise or be referred to as bumps, pillars, pads, or solder balls. Component terminals 125 can be provided as electrical contacts between electronic component 120 and substrate 110. Component terminals 125 can be coupled to conductive structure 112. For example, component terminals 125 can be coupled to inner contact pads 112a of conductive structure 112 by a mass reflow process, a thermal compression process, or a laser bonding process. In some examples, component terminals 125 can comprise copper (Cu), lead (Pb), tin (Sn), aluminum (Al), palladium (Pd), titanium (Ti), tungsten (W), titanium/tungsten (Ti/W), nickel (Ni), gold (Au), or silver (Ag) In other examples, component interconnects 125 can be provided on lower side 120b of electronic component 120 by electroplating, electroless plating, sputtering, PVD, CVD, MOCVD, ALD, LPCVD, or PECVD. For example, after providing a photoresist pattern for exposing bond pads of electronic component 120, component interconnects 125 can be provided so as to contact exposed bond pads on lower side 120b of electronic component 120. In some examples, the thickness of component interconnects 125 can range from about 1 μm to about 2 μm, and the width and pitch of component interconnects 125 can range from about 5 μm to about 10 μm.

In some examples, pick-and-place equipment can pick up electronic component 120 and place electronic component 120 on substrate inner side 110a of substrate 110. Component interconnects 125 of electronic component 120 can be located on inner contact pads 112a of substrate 110. Subsequently, component interconnects 125 of electronic component 120 can be in contact with and bonded to inner contact pads 112a through a mass reflow process, a thermal compression process, or a laser bonding process. In some examples, electronic component 120 can comprise or be referred to as a die, a chip, or a package. In some examples, the overall thickness of electronic component 120 can range from about 0.3 mm to about 9 mm, and the area of electronic component 120 can range from about 0.5 mm×0.5 mm to about 70 mm×70 mm. In some examples, electronic component 120 or other electronic components can be provided on substrate outer side 110b of substrate 110.

In some examples, electronic component 120′ can be provided outside dam 115 on substrate inner side 110a. Electronic component 120′ can comprise component interconnects 125′. In some examples, electronic component 120′ and component interconnects 125′ can have corresponding elements, features, materials or manufacturing methods similar to those of electronic component 120 and component interconnects 125. However, in some examples, electronic component 120′ does not include or is devoid of conductor 121 over the side of electronic component 120′ distal to substrate 110. Electronic component 120′ can comprise or be referred to as a die, a chip, a package, or a passive element. For example, electronic component 120′ can comprise a capacitor, a resistor or an inductor. In some examples, the thickness of electronic component 120′ can range from about 50 μm to about 2000 μm.

Although electronic component 120′ is shown as being in a face-down or flip-chip configuration where component terminals are positioned on the lower side, electronic component 120′ can be in a face-up or wire-bonded configuration where component terminals are positioned on the upper side. In this example, the lower side of electronic component 120′ can comprise or be referred to as an inactive side, and the upper side can comprise or be referred to as an active side. In this example, the inactive side can be adhered to substrate inner side 110a of substrate 110. Component terminals can be positioned on the upper side and electronic component 120′ can be provided as a face-up or wire-bonded component. The lower side of electronic component 120′ can be adhered to substrate inner side 110a of substrate 110 through an interface material. The component terminals of electronic component 120′ can be electrically connected to substrate inward terminals 112a of substrate 110 through different component interconnects, such as conductive wires. For example, the conductive wires can bond component terminals to inner contact pads 112a of substrate 110 by wire bonding equipment using conductive wires. In some examples, the conductive wires can comprise gold wires, copper wires, or aluminum wires.

FIG. 2C shows electronic device 100 at a later stage of manufacture. In the example shown in FIG. 2C, underfill 130 can be provided between electronic component 120 and substrate 110. In some examples, underfill 130 can comprise or be referred to as capillary underfill (CUF), molded underfill (MUF), non-conductive paste (NCP), non-conductive film (NCF), or anisotropic conductive film (ACF). In some examples, underfill 130 can comprise epoxy, a thermoplastic material, a thermosetting material, polyimide, polyurethane, a polymeric material, filled epoxy, a filled thermoplastic material, a filled thermosetting material, filled polyimide, filled polyurethane, a filled polymeric material, or a fluxing underfill. In some examples, underfill 130 is interposed between lower side 120b of electronic component 120 and substrate inner side 110a. In some examples, underfill 130 can cover or surround component interconnects 125. Underfill 130 contacts substrate inner side 110a of substrate 110 and lower side 120b of electronic component 120. In some examples, underfill 130 can cover, at least, a lower portion of lateral sides 120c of electronic component 120. In some examples, underfill 130 can prevent or reduce occurrences of electronic component 120 being separated from substrate 110. In some examples, the thickness of underfill 130 can range from about 80 μm to about 800 μm.

In some examples, when electronic component 120′ is in a face-down or flip-chip configuration, underfill 130′ can be located between electronic component 120′ and substrate 110. Underfill 130′ can have corresponding elements, features, materials, or manufacturing methods similar to those of underfill 130. FIGS. 2D and 2E show cross-sectional views of electronic device 100 at a later stage of manufacture. In the example, shown in FIGS. 2D and 2E, cover structure 150 can be provided over substrate 110 and electronic components 120 and 120′. In some examples, cover structure 150 can comprise or be referred to as a lid, a lid structure, or a shield. In some examples, cover structure 150 can comprise a metal material, such as copper, a copper alloy, nickel, a nickel alloy, or stainless steel. Cover structure 150 can comprise upper wall 152 and sidewalls 151. In some examples, cover structure 150 or just upper wall 152 comprises a thermally conductive material configured to conduct heat away from electronic component 120 through TIM 140.

In the present example, cover structure 150 is configured as a multiple-piece structure. In some examples, cover structure 150 can be referred to as or comprise a heat sink, a heat dissipation plate, a shield, a cap cover, an encapsulation part, a protection part, a package, or a body. In some examples, the area of cover structure 150 can range from about 0.5 mm×0.5 mm to about 70 mm×70 mm.

In some examples, sidewalls 151 can be formed on the edge (or perimeter) of upper wall 152 and can extend downward from upper wall 152. In some examples, sidewalls 151 can be continuously provided on the edge of upper wall 152. In some examples, sidewalls 151 can support upper wall 152. In some examples, sidewalls 151 can cover electronic components 120 and 120′ in the lateral direction.

Upper wall 152 and sidewalls 151 can define cavity 153. In some examples, the thickness of cover structure 150 can range from about 300 μm to about 4000 μm. The thickness of cover structure 150 can be defined as the sum of the thickness of upper wall 152 and the thickness of sidewall 151. Upper wall 152 also can be referred to as an upper cover wall or an upper lid wall. Sidewalls 151 also can be referred to as cover sidewalls, lid sidewalls, or a stiffener. Although sidewalls 151 is referred to in the plural, it is understood that sidewalls 151 can be a single-piece sidewall structure with portions oriented in different directions. Cavity 153 also can be referred to as a lid cavity.

In the example shown in FIG. 2D, sidewalls 151 are provided on substrate inner side 110a of substrate 110. In some examples, sidewalls 151 are spaced apart from electronic components 120 and 120′ on substrate inner side 110a of substrate 110 and can be provided to laterally surround electronic components 120 and 120′. The lower side of sidewalls 151 can be coupled to substrate inner side 110a through bonding material 170a. Bonding material 170a can be provided on substrate inner side 110a or on the lower side of sidewalls 151. In some examples, bonding material 170a can be supplied (or dispensed) on the bottom side of sidewalls 151, and sidewalls 151 can be coupled to substrate 110 by curing bonding material 170a in response to disposing sidewalls 151 on substrate 110. The bottom side of sidewalls 151 can be coupled to substrate inner side 110a of substrate 110 through bonding material 170a. In some examples, pick-and-place equipment can pick up sidewalls 151 to align and place sidewall 151 onto bonding material 170a provided on substrate 110. In some examples, sidewalls 151 can comprise a ring structure in the plan view, such as a square ring. Sidewalls 151 can be placed at an outer periphery of substrate 110 and electronic components 120 and 120′ can be located inside the periphery. In some examples, bonding material 170a can be applied to substrate inner side 110a of substrate 110 or the lower side of sidewalls 151 by dispensing. In some examples, bonding material 170a can comprise or be referred to as an interface material, an adhesive, or a solder. In some examples, bonding material 170a can comprise a thermally curable adhesive, a photo-curable adhesive, or a non-curable adhesive (e.g., a rubber-based adhesive, an acryl-based adhesive, a vinyl alkyl ether-based adhesive, a silicone-based adhesive, a polyester-based adhesive, a polyamide-based adhesive, or a urethane-based adhesive). In some examples, bonding material 170a can be dielectric. In some examples, bonding material 170a can be electrically conductive. In some examples, the thickness of bonding material 170a can range from about 30 μm to about 300 μm.

In some examples, after sidewalls 151 are coupled to substrate 110 through bonding material 170a, bonding material 170b can be applied to the upper side of sidewalls 151 or the lower side of upper wall 152 (FIG. 2E) by dispensing. Bonding material 170b can be referred to as an interface material, an adhesive, or a solder and comprises materials similar to bonding material 170a. In some examples, the thickness of bonding material 170b can range from about 5 μm to about 200 μm. In some examples, the sum of thicknesses of sidewalls 151, bonding material 170a, and bonding material 170b can be greater than the thickness of electronic component 120. In some examples, the sum of thicknesses of sidewalls 151, bonding material 170a, and bonding material 170b can be about 0.2 μm to about 200 μm greater than the thickness of electronic component 120. In some examples, the thickness of sidewalls 151 can range from about 50 μm to about 1600 μm.

FIG. 2E shows electronic device 100 at a later stage of manufacture. In the example shown in FIG. 2E, upper wall 152 can be provided. Upper wall 152 can include inner side 152a and outer side 152b. Outer side 152b is opposite to (i.e., oriented away from) inner side 152a. In some examples, upper wall 152 can comprise a substantially rectangular flat plate. The thickness of upper wall 152 can refer to the distance between outer side 152b and inner side 152a and can range from about 200 μm to about 3000 μm. TIM 140 can be provided over inner side 152a of upper wall 152. In some examples, inner side 151a is spaced apart from conductor 121 so that inner side 151a does not directly contact conductor 121. In the present example, inner side 152a overlies and faces conductor 121.

TIM 140 can be provided over inner side 152a of upper wall 152. In some examples, TIM 140 can be in contact with and electrically connected to upper wall 152. In some examples, TIM 140 can comprise or be referred to as an interface material or an adhesive. TIM 140 can be provided between upper wall 152 and electronic component 120 (FIG. 2F). In some examples, TIM 140 can contact inner side 152a of upper wall 152 and the top side of electronic component 120. In some examples, TIM 140 can comprise one layer or multiple layers.

In some examples, TIM 140 can comprise a metallic material. TIM 140 can include a thermally conductive material such as solder or solder paste. Examples of such thermal interface materials include metal alloy materials, such as gallium, gallium alloys (e.g., alloys with indium, tin, and zinc), silver alloys, tin-silver, indium, and indium alloys. Since TIM 140 includes a thermally conductive material, heat generated from electronic component 120 can be easily transferred to cover structure 150. In some examples, TIM 140 can be applied to inner side 152a of upper wall 152 by dispensing, printing, sputtering, electroless plating, electrolytic plating, PVD, CVD, MOCVD, ALD, LPCVD, or PECVD.

In some examples, the thickness of TIM 140 can range from about 0.2 μm to about 200 μm. In some examples, the thickness of TIM 140 can range from about 20% to about 40% of the total thickness of electronic component 120. The plane size, plan-view area, footprint, or area of TIM 140 can be larger than the plane size, plan view area, footprint, or area of electronic component 120. For example, the plane size of TIM 140 can range from about 10% to about 15% greater than the plane size of electronic component 120. In this way, the volume of TIM 140 results in a shape or structure after a curing process that covers lateral sides 120c of electronic component 120. In some examples, the shape or structure of TIM 140 along its edges 140a can be convexly rounded after the curing process. In some examples, TIM 140 can be located at the center of inner side 152a of upper wall 152 when electronic device is centrally located on substrate 110. In other examples, TIM 140 is located on inner side 152a corresponding to the location of electronic device 120 on substrate 110.

FIG. 2F shows a cross-sectional view of electronic device 100 at a later stage of manufacture. In the example shown in FIG. 2F, upper wall 152 is coupled to sidewalls 151. In some examples, inner side 152a of upper wall 152 can be coupled to sidewalls 151 through bonding material 170b described previously. In some examples, edges of inner side 152a of upper wall 152 can be coupled to sidewalls 151 to define cavity 153. Electronic components 120 and 120′ can be accommodated in or enclosed within cavity 153. In some examples, pick-and-place equipment can pick up upper wall 152 to align and place upper wall 152 onto bonding material 170b over sidewalls 151. TIM 140 can be aligned and placed onto electronic component 120. In some examples, TIM 140 can be evenly aligned with electronic component 120 so that TIM 140 generally overlaps with electronic component 120 in a uniform manner. In some examples, TIM 140 extends outward from each side of electronic component 120 in a generally equal amount.

In some examples, TIM 140 can be coupled to conductor 121 of electronic component 120 so that TIM 140 is interposed between conductor 121 and inner side 151a of upper wall 152. In some examples, TIM 140 can be in contact with conductor 121 of electronic component 120 and upper wall 152 of cover structure 150. Subsequently, a reflow and cure process can be used to affix TIM 140 to upper wall 152 and conductor 121. In some examples, TIM 140 can be reflowed and cured through a curing process using heat, light, ultraviolet rays, and laser. In some examples, TIM 140 can be in contact with lateral sides 120c of electronic component 120. In some examples, TIM 140 contacts or overlaps lateral edges 121a of conductor 121. In some examples, TIM 140 can be in contact with the lateral sides 120c of electronic component 120 and underfill 130. Underfill 130 can prevent TIM 140 from contacting component interconnects 125 of electronic component 120. In some examples, TIM 140 can be contained within dam 115. In some examples, dam 115 is configured to reduce or contain flow of TIM 140 external from dam 115. In some examples, TIM 140 can be in contact with dam 115. In some examples, TIM 140 can be in contact with an inner side (e.g., the side proximate to electronic device 120) and top side of dam 114. In some examples, an outer side (e.g., the side distal to electronic component 120) can be substantially devoid of TIM 140. In some examples, TIM 140 can be laterally interposed between dam 115 and underfill 130. In some examples, TIM 140 can be located within the cavity or peripheral boundary of dam 115. Adhesion of TIM 140 with electronic component 120 can be improved through conductor 121 provided on electronic component 120. Among other things, this improves thermal performance and the reliability of electronic device 100. In some examples, electronic component 120′ is devoid of TIM 140.

In some examples, the curing process of TIM 140 can be used to cure bonding materials 170a and 170b to affix upper wall 152 to sidewalls 151 and to affix sidewalls 151 to substrate 110. When bonding materials 170a and 170b are cured through the curing process, cover structure 150 can be adhered and fixed to substrate 110. Cover structure 150 can cover and enclose electronic components 120 and 120′ to protect electronic components 120 and 120′ from external elements.

Dam 115 can prevent or reduce the flow of TIM 140 outside of dam 115 during reflow and curing processes. By the reflow and curing processes and the pre-selected dimensions of TIM 140 compared to electronic component 120, TIM 140 comprises lateral edges that cover the lateral sides 120c of electronic component 120. In some examples, TIM 140 comprises lateral edges 140a that are convexly rounded outward from lateral sides 120c of electronic component 120 in a cross-sectional view. The convexly rounded outward shape helps to reduce stresses around electronic component 120. In some examples, when dam 115 is made of a conductive material and connected to a ground pad of conductive structure 112, TIM 140 can be in contact with and electrically connected to dam 115. In some examples, cover structure 150 can be electrically connected to ground through TIM 140 and dam 115. In this way, cover structure 150 can shield electronic components 120 and 120′ to reduce the effects of external disturbances, such as electromagnetic interference. In addition, dam 115 can contain TIM 140 and reduce any flow of TIM 140 to other regions of substrate 110 to improve the reliability of electronic device 100. TIM 140 can be interposed between cover structure 150 and substrate 110 inside the cavity of dam 115. TIM 140 is configured to improve the transfer of heat generated from electronic component 120 to cover structure 150. In some examples, an external heat transfer device can be coupled to upper wall 152.

FIG. 2G shows a cross-sectional view of electronic device 100 at a later stage of manufacture. In the example shown in FIG. 2G, external interconnects 160 can be provided on substrate lower side 110b of substrate 110. External interconnects 160 can be coupled to conductive structure 112 exposed from substrate outer side 110b of substrate 110. For example, external interconnects 160 can be coupled to outer contact pads 112b of conductive structure 112. In some examples, external interconnects 160 can comprise or be referred to as solder balls, solder coated metal (e.g., copper) core balls, pillars, pillars with solder caps, or bumps with solder caps. External interconnects 160 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. In some examples, external interconnects 160 can be provided through a reflow process after forming a conductive material including solder on substrate lower side 110b of substrate 110 in a ball drop method. External interconnects 160 can couple electronic device 100 to an external device. In some examples, the thickness of each of external interconnects 160 can range from about 50 μm to about 1000 μm.

In some examples, during the reflow and curing processes of external interconnects 160, TIM 140 can be further reflowed and cured. However, with TIM 140 comprising a structure covering lateral sides 120c of electronic component 120 between cover structure 150 and substrate 110, it was found in practice that TIM 140 can be more stable against shape changes that result from the further reflow and cure processing of external interconnects 160.

In some examples, a plurality of electronic devices can be provided on a single substrate assembly. A subsequent singulation process can separate the single substrate assembly into individual electronic devices 100. In some examples, electronic device 100 can comprise substrate 110, electronic component 120, underfill 130, TIM 140, cover structure 150, and external interconnects 160.

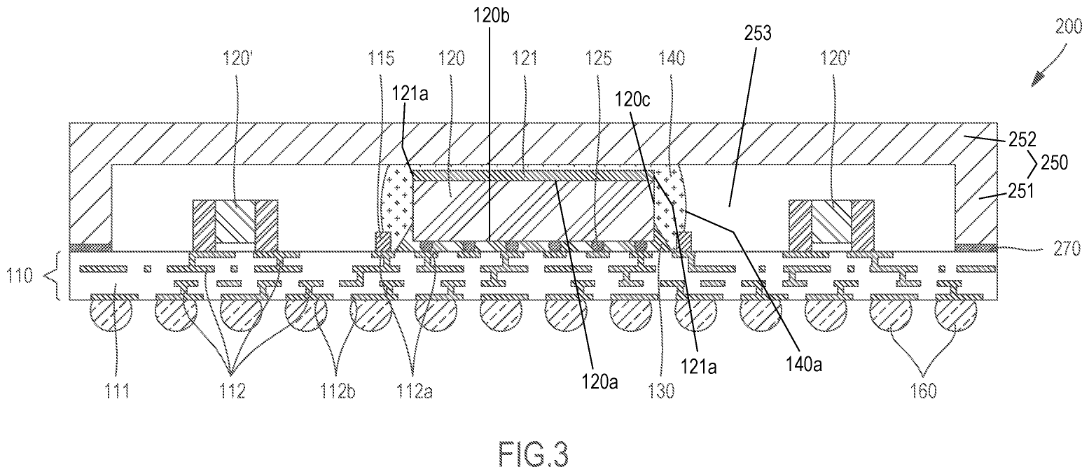

FIG. 3 shows a cross-sectional view of an example electronic device 200. In the example shown in FIG. 3, electronic device 200 can comprise substrate 110, electronic component 120, electronic component 120′, underfill 130, TIM 140, cover structure 250, external interconnects 160, and bonding material 270. In some examples, electronic device 200 can comprise similar elements, features, materials, or formation processes to those of electronic device 100, as previously described. Cover structure 250 can comprise sidewalls 251, upper wall 252, and cavity 253. Electronic components 120′ in electronic device 200 are illustrated, for example, as passive components, such as capacitors, resistors, or inductors, which can be coupled to conductive structure 112 of substrate 110.

In some examples, cover structure 250 can comprise or be referred to as a lid, a lid structure, or a shield. In some examples, cover structure 150 can comprise a metal material, such as copper, a copper alloy, nickel, a nickel alloy, or stainless steel. Cover structure 250 can comprise sidewalls 251 and upper wall 252. In the present example, cover structure 250 is configured as a single-piece or integrated structure. In some examples, cover structure 250 can be referred to as or comprise a heat sink, a heat dissipation plate, a shield, a cap cover, an encapsulation part, a protection part, a package, or a body.

In some examples, sidewalls 251 can be formed on the edge (or perimeter) of upper wall 252 and can extend downward from upper wall 252. In some examples, sidewalls 251 can be continuously provided on the edge of upper wall 252. In some examples, sidewalls 251 can support upper wall 252. In some examples, sidewalls 251 can cover electronic components 120 and 120′ in the lateral direction.

Upper wall 252 and sidewalls 251 can define cavity 253. In some examples, the thickness of cover structure 250 can range from about 300 μm to about 4000 μm. The thickness of cover structure 250 can be defined as the sum of the thickness of upper wall 252 and the thickness of sidewall 251. Upper wall 252 also can be referred to as an upper cover wall or an upper lid wall. Sidewalls 251 also can be referred to as cover sidewalls, lid sidewalls, or a stiffener. Cavity 253 also can be referred to as a lid cavity.

In some examples, cover structure 250 can be coupled to substrate 110 with bonding material 270 interposed between sidewalls 251 and substrate 110. Bonding material 270 and the processes used to provide bonding material 270 can be similar to those described previously for bonding material 170b.

In summary, electronic devices and methods of manufacturing have been described. In some examples, a cover structure configured to transfer heat is coupled to a substrate. An electronic component is interposed between the substrate and the cover structure and a TIM material is interposed between the electronic component and the cover structure. In some examples, the TIM material is electrically coupled to a ground node within the substrate. In some examples, a conductive dam structure surrounds and the electronic component and the TIM material contacts the conductive dam structure. In some examples, the conductive dam structure is connected to the ground node in the substrate and the conductive dam structure couples the TIM material to the ground node. In some examples, the cover structure comprises an integrated or single-piece structure. In other examples, the cover structure comprises a multi-piece structure. In some examples, a conductor is over an upper side of the electronic component and is interposed between the upper side of the electronic component and the TIM material to enhance adhesion and improve heat transfer. Among other things, electronic devices and methods provide improved EMI shielding and improve heat transfer capabilities compared to previous electronic devices and methods.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising:
a substrate outer side;
a substrate inner side;
a dielectric structure; and
a conductive structure;
an electronic component comprising:
an upper side;
a lower side opposite to the upper side and coupled to the substrate inner side;
lateral side connecting the upper side to the lower side; and
a conductor on the upper side;
a cover structure comprising:
sidewalls coupled to the substrate inner side; and
an upper wall coupled to the sidewalls and comprising an inner side spaced apart from the conductor; and
a thermal interface material (TIM) contacting and interposed between the conductor and the inner side of the upper wall, wherein:
the TIM covers the conductor and the lateral side of the electronic component.

2. The electronic device of claim 1, further comprising:
component interconnects coupling the lower side of the electronic component to the conductive structure; and
an underfill interposed between the lower side of the electronic component and surrounds the component interconnects.

3. The electronic device of claim 2, wherein:
the upper wall comprises a thermally conductive material; and
the TIM contacts the underfill.

4. The electronic device of claim 1, wherein:
the TIM contacts the lateral side of the electronic component.

5. The electronic device of claim 1, wherein:
the TIM comprises edges that are convexly rounded outward from the lateral side of the electronic component.

6. The electronic device of claim 1, wherein:
the TIM comprises a metallic material; and
the cover structure comprises a multi-piece structure.

7. The electronic device of claim 1, further comprising:
a dam coupled to the substrate inner side,
wherein:
the dam is laterally spaced apart from and surrounds at least the lateral side of the electronic component; and
the TIM extends between the lateral side of the electronic component and the dam.

8. The electronic device of claim 7, wherein:
the TIM comprises a first electrically conductive material; and
the dam comprises a second electrically conductive material.

9. The electronic device of claim 8, wherein:
the TIM is coupled by the dam to a ground of the conductive structure.

10. An electronic device, comprising:
a substrate comprising:
a substrate outer side;
a substrate inner side;
a dielectric structure; and
a conductive structure;
a first electronic component comprising:
a lower side coupled to the substrate inner side;
an upper side opposite to the lower side and distal to the substrate inner side; and
lateral sides connecting the upper side to the lower side;
a cover structure comprising:
sidewalls coupled to the substrate inner side; and
an upper wall coupled to the sidewalls and comprising an inner side spaced apart from and overlying the upper side of the first electronic component; and
a thermal interface material (TIM) interposed between the upper side of the first electronic component and the inner side of the upper wall, wherein:
the TIM covers the upper side and the lateral sides of the first electronic component; and
the TIM is coupled to the conductive structure.

11. The electronic device of claim 10, further comprising:
a conductor over the upper side and extending to the lateral sides; and
an underfill interposed between the lower side of the first electronic component and the substrate inner side;
wherein:
the TIM contacts the underfill and the lateral sides of the first electronic component; and
the TIM covers the conductor.

12. The electronic device of claim 11, wherein:
the conductor comprises lateral edges substantially co-planar with the lateral sides of the first electronic component; and
the TIM overlaps the lateral edges of the conductor.

13. The electronic device of claim 10, further comprising:
a dam coupled to the substrate inner side and laterally spaced apart from the first electronic component so a portion of the substrate inner side is between the dam and the first electronic component.

14. The electronic device of claim 13, wherein:
the TIM comprises a first conductive material;
the dam comprises a second conductive material; and
the dam is coupled to the conductive structure of the substrate.

15. The electronic device of claim 14, wherein:
the TIM is coupled to the conductive structure of the substrate through the dam.

16. The electronic device of claim 10, wherein:
the TIM comprises edges that are convexly rounded outward from the lateral sides of the first electronic component in a cross-sectional view.

17. The electronic device of claim 10, further comprising:
a second electronic component coupled to the substrate inner side;
wherein:
the second electronic component is devoid of the TIM.

18. A method of manufacturing an electronic device, comprising:
providing a substrate comprising:
a substrate outer side;
a substrate inner side;
a dielectric structure; and
a conductive structure;
providing an electronic component comprising:
an upper side;
a lower side opposite to the upper side and coupled to the substrate inner side;
a lateral side connecting the upper side to the lower side; and
a conductor on the upper side;
coupling the lower side of the electronic component to the substrate inner side;
providing a cover structure comprising:
sidewalls; and
an upper wall coupled to the sidewalls and comprising an inner side spaced apart from the conductor;
coupling the sidewalls to the substrate inner side; and
providing a thermal interface material (TIM) on the conductor and interposed between the conductor and the inner side of the upper wall and covering the conductor and the lateral side of the electronic component.

19. The method of claim 18, wherein:
the electronic component comprises a first thickness and a first footprint;
providing the TIM comprises providing the TIM on the inner side of the upper wall before coupling the sidewalls to the substrate inner side;
the TIM comprises a second thickness and a second footprint;
the second thickness is in a range from about 20% to about 40% of the first thickness; and
the second footprint is about 10% to about 15% greater than the first footprint.

20. The method of claim 18, further comprising:
providing an underfill interposed between the lower side of the electronic component and the substrate inner side;
wherein:
coupling the lower side of the electronic component comprises coupling the lower side to the conductive structure with component interconnects; and
providing the underfill comprises surrounding the component interconnects;
providing the TIM comprises the TIM comprises edges that are convexly rounded outward from the lateral side of the electronic component in a cross-sectional view.
